(19) United States
(12) Patent Application Publication
(10) Pub. No.: US 2025/0015192 A1
(43) Pub. Date: Jan. 9, 2025

(54) THIN FILM TRANSISTOR, ARRAY SUBSTRATE, AND DISPLAY PANEL

(71) Applicant: GUANGZHOU CHINA STAR OPTOELECTRONICS SEMICONDUCTOR DISPLAY TECHNOLOGY CO., LTD., Guangzhou (CN)

(72) Inventors: Mingjiue YU, Guangzhou (CN); Shimin GE, Guangzhou (CN)

(21) Appl. No.: 18/455,285

(22) Filed: Aug. 24, 2023

(30) Foreign Application Priority Data
Jul. 6, 2023 (CN) 202310831160.X

(51) Int. Cl. H01L 29/786; H01L 27/12

(52) U.S. Cl. CPC H01L 29/7869; H01L 27/1225; H01L 29/78633; H01L 29/78696; G02F 1/1368

(57) ABSTRACT

A thin film transistor includes a gate, a source, a drain, and an active layer. The active layer includes first and second oxide layers that are stacked, the source and the drain are both disposed at a side of the second oxide layer away from the first oxide layer, the first oxide layer is a crystalline oxide layer, and the second oxide layer is a lanthanide oxide layer. When the gate is disposed at a side of the first oxide layer away from the second oxide layer, an atomic proportion of an indium element in the first oxide layer is greater than that of the second oxide layer; when the gate is disposed at the side of the second oxide layer away from the first oxide layer, the atomic proportion of the indium element in the first oxide layer is less than that of the second oxide layer.

### CROSS-REFERENCE TO RELATED APPLICATION

This application claims priority to Chinese Patent Application No. 202310831160.X, filed in the China National Intellectual Property Administration on Jul. 6, 2023, the disclosure of which is hereby incorporated by reference in its entirety.

### TECHNICAL FIELD

The present disclosure relates to a technical field of display, and in particular to a thin film transistor, an array substrate, and a display panel.

### BACKGROUND

A thin film transistor (TFT) is a core device of a display panel. Depending on semiconductor material of an active layer of the thin film transistor, the thin film transistor mainly includes an oxide semiconductor thin film transistor and an amorphous silicon semiconductor thin film transistor. The oxide semiconductor thin film transistors has attracted wide attention due to its high mobility, excellent uniformity, good transparency, low cost, and the like, and is increasingly applied to large-sized high-resolution display fields. However, the oxide semiconductor device is prone to generate photogenerated carriers under light, which affects the stability of the oxide semiconductor thin film transistor.

### SUMMARY

An embodiment of the present disclosure provides a thin film transistor including a gate, a source, a drain, and an active layer. The active layer includes a first oxide layer and a second oxide layer that are stacked, the source and the drain are both located at a side of the second oxide layer away from the first oxide layer, the first oxide layer is a crystalline oxide layer, and the second oxide layer is a lanthanide oxide layer.

The gate is disposed at a side of the first oxide layer or the second oxide layer, and when the gate is disposed at a side of the first oxide layer away from the second oxide layer, an atomic proportion of an indium element in the first oxide layer is greater than an atomic proportion of an indium element in the second oxide layer; when the gate is disposed at the side of the second oxide layer away from the first oxide layer, the atomic proportion of the indium element in the first oxide layer is less than the atomic proportion of the indium element in the second oxide layer.

In a thin film transistor provided in an embodiment of the present disclosure, the atomic proportion of the indium element in the first oxide layer gradually decreases in a direction away from the gate, and the atomic proportion of the indium element in the second oxide layer gradually decreases in the direction away from the gate.

In a thin film transistor provided in an embodiment of the present disclosure, an atomic proportion of an oxygen element in the first oxide layer gradually increases in the direction away from the gate, and an atomic proportion of an oxygen element in the second oxide layer gradually increases in the direction away from the gate.

In a thin film transistor provided in an embodiment of the present disclosure, a number of atoms of the indium element in the first oxide layer accounts for 50% to 100% of a number of atoms of a metal element in the first oxide layer, and a proportion of a number of atoms of the oxygen element in the first oxide layer ranges from more than 50%; a number of atoms of the indium element in the second oxide layer accounts for 50% to 100% of a number of atoms of a metal element in the second oxide layer, and a proportion of a number of atoms of the oxygen element in the second oxide layer ranges from more than 50%.

In a thin film transistor provided in an embodiment of the present disclosure, a proportion of a number of atoms of lanthanide in the lanthanide oxide layer ranges from 0.05% to 3%.

In a thin film transistor provided in an embodiment of the present disclosure, the thin film transistor further includes a first auxiliary layer provided corresponding to the active layer, and the first auxiliary layer is disposed at the side of the first oxide layer away from the second oxide layer.

In a thin film transistor provided in an embodiment of the present disclosure, the thin film transistor further includes a second auxiliary layer provided corresponding to the active layer, and the second auxiliary layer is disposed at the side of the second oxide layer away from the first oxide layer.

In a thin film transistor provided in an embodiment of the present disclosure, the second auxiliary layer includes an insulating portion and conductor portions located at both sides of the insulating portion, and the conductor portions are provided corresponding to the source and the drain respectively.

An embodiment of the present disclosure further provides an array substrate including the thin film transistor of one of the foregoing embodiments.

An embodiment of the present disclosure further provides a display panel including a first substrate and a second substrate disposed opposite to each other, one of the first substrate and the second substrate includes an array substrate of one of the foregoing embodiments.

### BRIEF DESCRIPTION OF THE DRAWINGS

In order to more clearly explain the embodiments or the technical solutions in the prior art, the following will briefly introduce the drawings required in the description of the embodiments or the prior art, and it may be apparent that the drawings in the following description are only some embodiments of the present disclosure. For those skilled in the art, without paying any creative work, other drawings can be obtained based on these drawings.

FIG. 1 is a schematic diagram of a first cross-sectional structure of a thin film transistor according to an embodiment of the present disclosure.

FIG. 2 is a schematic diagram of a second cross-sectional structure of a thin film transistor according to an embodiment of the present disclosure.

FIG. 3 is a schematic diagram of a third cross-sectional configuration of a thin film transistor according to an embodiment of the present disclosure.

FIG. 4 is a schematic diagram of a fourth cross-sectional structure of a thin film transistor according to an embodiment of the present disclosure.

FIG. 5 is a schematic diagram of a fifth cross-sectional structure of a thin film transistor according to an embodiment of the present disclosure.

FIG. 6 is a schematic diagram of a sixth cross-sectional structure of a thin film transistor according to an embodiment of the present disclosure.

### DETAILED DESCRIPTION

The following description of the embodiments is made with reference to the accompanying drawings to illustrate specific embodiments in which the present disclosure may be implemented. The direction terms mentioned in the present disclosure, such as [up], [down], [front], [back], [left], [right], [inner], [outer], [side], and the like, are only the direction of the attached drawings. Therefore, the directional terms used are used to describe and understand the present disclosure, rather than to limit the present disclosure. In the drawings, units with similar structures are indicated by the same reference numerals. In the drawings, thickness of some layers and regions is exaggerated for clarity and ease of description. That is, the dimensions and thickness of each component shown in the drawings are arbitrarily shown, but the present disclosure is not limited thereto.

Referring to FIG. 1, FIG. 1 is a schematic diagram of a first cross-sectional structure of a thin film transistor according to an embodiment of the present disclosure. The thin film transistor 100 includes a gate 10, a source 20, a drain 30, and an active layer 40, the active layer 40 includes a first oxide layer 41 and a second oxide layer 42 that are stacked, the source 20 and the drain 30 are both located at a side of the second oxide layer 42 away from the first oxide layer 41, the first oxide layer 41 is a crystalline oxide layer, and the second oxide layer 42 is a lanthanide oxide layer.

In the present embodiment, the active layer 40 of the thin film transistor 100 includes the first oxide layer 41 and the second oxide layer 42. The first oxide layer 41 is the crystalline oxide layer and the second oxide layer 42 is the lanthanide oxide layer. After crystallization of the crystalline oxide layer, the defect states are reduced, and fewer photogenerated carriers are generated when exposed to light, thereby reducing a concentration of free carriers of the channel layer of the active layer 40. When the lanthanide oxide layer is illuminated, a shallow recombination center generated by a lanthanide element has a function of capturing a photogenerated carrier, thereby avoiding a device threshold voltage offset and an off-state current rising when the device is illuminated, improving the stability of the thin film transistor 100, and solving the problem of poor stability of the conventional oxide semiconductor thin film transistor.

Specifically, referring to FIG. 1, the thin film transistor 100 further includes a substrate on which the gate 10 is disposed. Alternatively, the substrate may be a rigid substrate or a flexible substrate. When the substrate is the rigid substrate, the rigid substrate may include, for example, a glass substrate. When the substrate is the flexible substrate, the flexible substrate may include, for example, a polyimide (PI) film or an ultra-thin glass film.

The gate 10 may be formed as a plurality of layers or a single layer including a low resistance material such as Al, Ti, Mo, Cu, Ni, or an alloy thereof, or a material having high corrosion resistance.

The gate insulating layer 51 covers the gate 10 and the substrate, and the gate insulating layer 51 may include an inorganic insulating material, for example, such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The gate insulating layer 51 may include a single layer or a plurality of layers including one or more of the inorganic insulating materials mentioned above.

The active layer 40 is provided on the gate insulating layer 51 and corresponds to the gate 10. The active layer 40 includes the first oxide layer 41 and the second oxide layer 42 that are stacked, the first oxide layer 41 is the crystalline oxide layer, and the second oxide layer 42 is the lanthanide oxide layer. Alternatively, material of the first oxide layer 41 includes one of semiconductor materials such as indium gallium oxide (IGO), indium gallium tin oxide (IGTO), indium oxide (InO), indium zinc oxide (IZO), or indium tin oxide (ITO). The first oxide layer 41 may be formed as the crystalline oxide layer by thermal annealing, laser crystallization, seed crystallization, or other crystallization methods.

The first oxide layer 41 is made of crystalline oxide, so that M-O bonding can be strengthened, the number of deep defect states (DOS) of the first oxide layer 41 can be reduced, fewer photogenerated carriers are generated when the first oxide layer 41 is exposed to light, the free carrier concentration of the channel layer of the active layer 40 can be reduced, and the photostability of the device may be improved. The crystalline oxide may also reduce the effect of hydrogen implantation during subsequent processes on the device to further improve the stability of the device.

The second oxide layer 42 is disposed at a side of the first oxide layer 41 away from the substrate, the second oxide layer 42 is disposed corresponding to the first oxide layer, and the outer boundary of the second oxide layer 42 is aligned with the outer boundary of the first oxide layer 41. The thickness of the second oxide layer 42 is greater than 150 angstroms, and the thickness of the first oxide layer 41 may be greater than or equal to the thickness of the second oxide layer 42.

Alternatively, the material of the second oxide layer 42 includes one of semiconductor materials such as indium zinc oxide IZO, indium oxide (InO), indium gallium zinc oxide (IGZO), indium tin zinc oxide (ITZO), or the like. The second oxide layer 42 is a lanthanide oxide layer formed by doping a lanthanide in the semiconductor material mentioned above. A proportion of the number of atoms of the lanthanide in the lanthanide oxide layer ranges from 0.05% to 3%, such as 0.05%, 0.1%, 0.6%, 0.8%, 1%, 1.5%, 1.8%, 2%, 2.6%, etc. When the proportion of the number of atoms of the lanthanide is too low, the function of capturing photogenerated carriers may not be realized. When the proportion of the number of atoms of the lanthanide is too high, the semiconductor characteristics of the second oxide layer 42 are affected. The lanthanide includes one of Pr, Dy, Yb, and the like.

The second oxide layer 42 is made of the lanthanide oxide. When the second oxide layer 42 is exposed to light, the shallow recombination center generated by the lanthanide element has a function of capturing the photogenerated carrier, thereby avoiding a device threshold voltage offset and an off-state current rising when the device is exposed to light, and improving the stability of the thin film transistor 100. Moreover, the use of lanthanide oxides can also improve the resistance to cupric acid etching and hydrogen diffusion of the second oxide layer 42, and further improve the stability of the device.

In the present embodiment, the crystalline oxide and the lanthanide oxide are used as the active layer 40, so that in addition to higher mobility, the photostability of the device is better than that of a general oxide device (e.g., IGZO), the defect states are reduced after the crystallization of the crystalline oxide layer, and the free carrier concentration of the channel layer of the active layer 40 is reduced due to fewer photogenerated carriers when the crystalline oxide layer is exposed to light. When the lanthanide oxide layer is illuminated, the shallow recombination center generated by the lanthanide element has the function of capturing the photogenerated carrier, thereby avoiding the device threshold voltage offset and the off-state current rising when the device is illuminated, improving the stability of the thin film transistor 100, and solving the problem of poor stability of the conventional oxide semiconductor thin film transistor 100.

Further, since the gate 10 is located at the side of the first oxide layer 41 away from the second oxide layer 42, an atomic proportion of the indium element in the first oxide layer 41 may be made larger than an atomic proportion of the indium element in the second oxide layer 42 to improve the mobility of the first oxide layer 41. Alternatively, the number of atoms of the indium element in the first oxide layer 41 accounts for 50% to 100% of the number of atoms of the metal element in the first oxide layer 41, such as 50%, 60%, 70%, 80%, 90%, 100%, etc., and the proportion of the number of atoms of the oxygen element in the first oxide layer 41 is in the range of more than 50%, such as 50%, 60%, 70%, etc. The number of atoms of the indium element in the second oxide layer 42 accounts for 50% to 100% of the number of atoms of the metal element in the second oxide layer 42, such as 50%, 60%, 70%, 80%, 90%, 100%, and the like, and the proportion of the number of atoms of the oxygen element in the second oxide layer 42 is in the range of more than 50%, such as 50%, 60%, 70%, etc. The proportion of the number of atoms of the element refers to the proportion of the number of atoms, for example, the proportion of the number of atoms of the indium element in the number of atoms of the metal element in the first oxide layer 41 is in the range of 50% to 100%, which refers to the percentage of the number of atoms of the indium element to the number of atoms of all metal elements in the first oxide layer 41.

In an embodiment, the atomic proportion of the indium element in the first oxide layer 41 gradually decreases in the direction away from the gate 10, and the atomic proportion of the oxygen element in the first oxide layer 41 gradually increases in the direction away from the gate 10. In this way, the portion of the first oxide layer 41 that is close to the gate 10 may have a higher atomic proportion of the indium element, so that the mobility of the first oxide layer 41 may be improved. At the same time, the stability of the thin film transistor 100 may be further improved, for example, the voltage stability and the light stability at the channel of the active layer may be improved, and the threshold voltage drift may be avoided. The atomic proportion refers to the proportion of the number of atoms.

Further, the atomic proportion of the indium element in the second oxide layer 42 also gradually decreases in a direction away from the gate 10, and the atomic proportion of the oxygen element in the second oxide layer 42 also gradually increases in the direction away from the gate 10. In this way, the portion of the second oxide layer 42 away from the gate 10 has a lower atomic proportion of the indium element, so that lanthanides with a higher proportion of the number of atoms may be provided, and thus the barrier performance of the second oxide layer 42 may be improved, for example, an etching liquid damage resistance performance.

With continued reference to FIG. 1, the source 20 and the drain 30 are disposed on the active layer 40 at opposite ends of the active layer 40, for example, the source 20 is disposed at one end of the active layer 40 and electrically connected to the one end of the active layer 40, and the drain 30 is disposed at the other end of the active layer 40 and is electrically connected to the other end of the active layer 40. Specifically, the source 20 and the drain 30 cover a side of the second oxide layer 42 away from the first oxide layer 41, and cover sidewalls of the ends of the second oxide layer 42 and the first oxide layer 41.

Alternatively, each of the source 20 and the drain 30 may include a conductive material including, for example, Mo, Al, Cu, and/or Ti, and may be a single layer or multiple layers including one or more of the conductive materials mentioned above.

A passivation layer 52 covers the source 20, the drain 30, the second oxide layer 42, and the gate insulating layer 51 to insulate moisture and oxygen and protect the source 20, the drain 30, and the active layer 40. The passivation layer 52 may include an inorganic insulating material, for example, such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The passivation layer 52 may be a single layer or multiple layers including one or more of the inorganic insulating materials mentioned above.

In an embodiment, referring to FIG. 2, FIG. 2 is a schematic diagram of a second cross-sectional structure of a thin film transistor 100 according to an embodiment of the present disclosure. It differs from the above embodiment in that the gate 10 is located at the side of the second oxide layer 42 away from the first oxide layer 41, and the atomic proportion of the indium element in the first oxide layer 41 is smaller than the atomic proportion of the indium element in the second oxide layer 42.

Specifically, the thin film transistor 100 further includes a light shielding layer 60, and the light shielding layer 60 is disposed on the substrate and corresponds to the active layer 40 to shield the active layer 40 from light. Material of the light shielding layer 60 may include a light shielding metal, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu). The light shielding layer 60 may be a single layer or multiple layers including one or more of the light shielding metal materials mentioned above.

A buffer layer 53 covers the light shielding layer 60 and the substrate. The buffer layer 53 may prevent undesirable impurities or contaminants (e.g., moisture, oxygen, etc.) from diffusing from the substrate into devices that may be damaged by these impurities or contaminants, while also providing a flat top surface. In order to improve the function of preventing moisture and other impurities from permeating through the substrate, the buffer layer 53 may be a silicon oxide film, a silicon nitride film, or multiple layers including the silicon oxide film and the silicon nitride film. Further, the buffer layer 53 may be formed of a plurality of layers having different refractive indices, so as to scatter external light incident from the outside.

The active layer 40 is disposed on the buffer layer 53, the gate insulating layer 51 is disposed on the active layer 40, the gate 10 is disposed on the gate insulating layer 51, and the gate 10 and the gate insulating layer 51 are each disposed corresponding to the active layer 40.

An interlayer insulating layer 54 covers the gate 10, the active layer 40, and the buffer layer 53, and the interlayer insulating layer 54 may include an inorganic insulating material, for example, such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂). The interlayer insulating layer 54 may be a single layer or multiple layers including one or more of the inorganic insulating materials mentioned above.

The source 20 and the drain 30 are disposed on the interlayer insulating layer 54 and electrically connected to the active layer 40 through via holes in the interlayer insulating layer 54. The passivation layer 52 covers the source 20, the drain 30, and the interlayer insulating layer 54. For other description, referring to the above-mentioned embodiments, and details are not described herein.

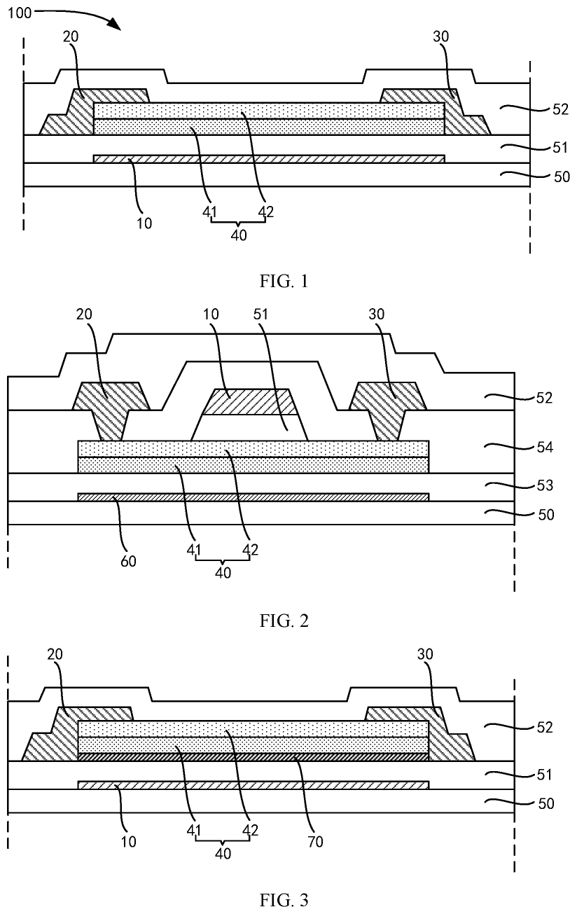

In an embodiment, referring to FIG. 3, FIG. 3 is a schematic diagram of a third cross-sectional structure of a thin film transistor 100 according to an embodiment of the present disclosure. It differs from the above embodiment in that the thin film transistor 100 further includes a first auxiliary layer 70 provided corresponding to the active layer 40, and the first auxiliary layer 70 is located at a side of the first oxide layer 41 away from the second oxide layer 42.

Specifically, referring to FIG. 3, the first auxiliary layer 70 is disposed at a side of the first oxide layer 41 close to the gate 10 and at a side of the gate insulating layer 51 away from the gate 10, and the first oxide layer 41 covers the first auxiliary layer 70. Alternatively, the first auxiliary layer 70 is a thin film of metal particles, for example, metal particles such as titanium or molybdenum. Thickness of the first auxiliary layer 70 ranges from 10 angstroms to 50 angstroms.

By forming the first auxiliary layer 70 having a thinner thickness before forming the active layer 40, the first auxiliary layer 70 may seize oxygen elements in the active layer 40, so that the first oxide layer 41 is easier to crystallize. Further, the metal element in the first auxiliary layer 70 forms a metal oxide after seizing the oxygen element in the active layer 40, and the first auxiliary layer 70 is in contact with the gate insulating layer 51, and the gate insulating layer 51 supplements oxygen element to the first auxiliary layer 70, so that the metal oxide formed by the first auxiliary layer 70 tends to have insulator characteristic, and the first auxiliary layer 70 does not affect the semiconductor characteristic of the first oxide layer 41 while facilitating crystallization of the first oxide layer 41. For other description, referring to the above-mentioned embodiments, and details are not described herein.

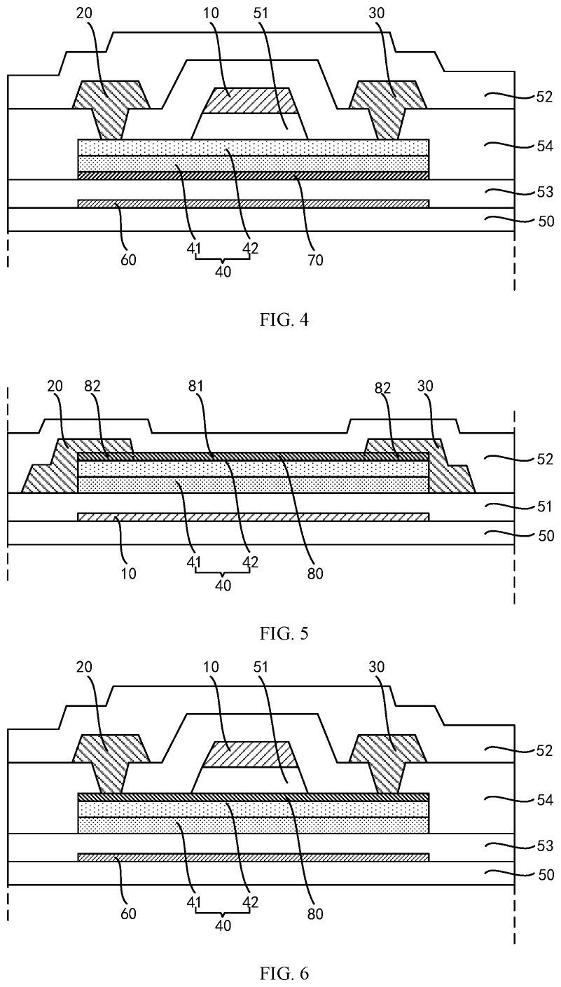

In an embodiment, referring to FIG. 4, FIG. 4 is a schematic diagram of a fourth cross-sectional structure of a thin film transistor 100 according to an embodiment of the present disclosure. It differs from the above embodiment in that the gate 10 is located at the side of the second oxide layer 42 away from the first oxide layer 41, the first auxiliary layer 70 is provided at the side of the first oxide layer 41 close to the light shielding layer 60 and is located at the side of the buffer layer 53 away from the light shielding layer 60, and the first oxide layer 41 covers the first auxiliary layer 70. For other description, referring to the above-mentioned embodiments, and details are not described herein.

In an embodiment, referring to FIG. 5, FIG. 5 is a schematic diagram of a fifth cross-sectional structure of a thin film transistor 100 according to an embodiment of the present disclosure. It differs from the above embodiment in that the thin film transistor 100 further includes a second auxiliary layer 80 provided corresponding to the active layer 40, and the second auxiliary layer 80 is located at the side of the second oxide layer 42 away from the first oxide layer 41.

Specifically, referring to FIG. 5, the second auxiliary layer 80 covers the second oxide layer 42, and the source 20 and the drain 30 cover opposite ends of the second auxiliary layer 80. The passivation layer 52 covers the source 20, the drain 30, and the second auxiliary layer 80. The second auxiliary layer 80 is a metal thin film, for example, a metal thin film such as titanium or molybdenum. Thickness of the second auxiliary layer 80 ranges from 1 nm to 5 nm.

By forming the second auxiliary layer 80 with a thinner thickness on the active layer 40, the second auxiliary layer 80 may seize the oxygen element in the active layer 40, so that the metal element in the second auxiliary layer 80 forms a metal oxide after seizing the oxygen element in the active layer 40. For example, when the second auxiliary layer 80 include Ti or Mo, the corresponding TiO₂, MoO that tend to have conductor characteristics are formed to improve the contact impedance. At the same time, a portion of the second auxiliary layer 80, which is not covered by the source 20 and the drain 30, is also in contact with the passivation layer 52, which supplements oxygen element to the second auxiliary layer 80, so that the metal oxide formed by the second auxiliary layer 80 tends to have the insulator characteristic, and thus the second auxiliary layer 80 forms an insulating portion 81 and conductor portions 82 on opposite sides of the insulating portion 81. The conductor portions 82 are provided corresponding to the source 20 and the drain 30, the source 20 and the drain 30 are electrically connected to the active layer 40 through the corresponding conductor portions 82, respectively. The insulating portion 81 may protect the active layer 40 from contact with the etching liquid. For other description, referring to the above-mentioned embodiments, and details are not described herein.

In an embodiment, referring to FIG. 6, FIG. 6 is a schematic diagram of a sixth cross-sectional structure of a thin film transistor 100 according to an embodiment of the present disclosure. It differs from the above embodiment in that the gate 10 is located at the side of the second oxide layer 42 away from the first oxide layer 41, the second auxiliary layer 80 is provided at the side of the second oxide layer 42 adjacent to the gate 10 and is located at the side of the gate insulating layer 51 away from the gate 10, and the second auxiliary layer 80 covers the second oxide layer 42. For other description, referring to the above-mentioned embodiments, and details are not described herein.

In an embodiment, an embodiment of the present disclosure further provides an array substrate, and the array substrate includes the thin film transistor 100 according to one of the foregoing embodiments.

In an embodiment, an embodiment of the present disclosure further provides a display panel, the display panel includes first and second substrates arranged opposite to each other, and one of the first and second substrates includes an array substrate according to one of the foregoing embodiments. The display panel includes a display panel such as a liquid crystal display panel.

It can be seen from the above embodiments that: the present disclosure provides a thin film transistor, an array substrate, and a display panel. The active layer of the thin film transistor includes a first oxide layer and a second oxide layer. The first oxide layer is the crystalline oxide layer, and the second oxide layer is the lanthanide oxide layer. When the crystalline oxide layer and the lanthanide oxide layer are used as active layers, in addition to having a higher mobility, the photostability of the device is better than that of a general oxide device (such as IGZO). After the crystalline oxide layer is crystallized, the defect states are reduced, and there is fewer photogenerated carriers when the crystalline oxide layer is exposed to light, thereby reducing a free carrier concentration of the channel layer of the active layer. When the lanthanide oxide layer is illuminated, the shallow recombination center generated by the lanthanide element has the function of capturing the photogenerated carrier, thereby avoiding a device threshold voltage offset and an off-state current rising when the device is illuminated, improving the stability of the thin film transistor, and solving the problem of poor stability of the conventional oxide semiconductor thin film transistor.

In the above-mentioned embodiments, the description of each embodiment has its own emphasis, and parts not described in detail in a certain embodiment may be referred to the related description of other embodiments.

The embodiments of the present disclosure are described in detail above, the principles and embodiments of the present disclosure are described herein with reference to specific embodiments. The description of the above embodiments is merely intended to assist in understanding the technical solution of the present disclosure and the core concepts thereof. It may be appreciated by those ordinary skilled in the art that modifications may still be made to the technical solutions described in the foregoing embodiments, or equivalent replacements may be made to some of the technical features therein. These modifications or substitutions do not cause the essence of the corresponding technical solutions to deviate from the scope of the technical solutions of the embodiments of the present disclosure.

What is claimed is:

1. A thin film transistor, wherein thin film transistor comprises a gate, a source, a drain, and an active layer, wherein the active layer comprises a first oxide layer and a second oxide layer that are stacked, the source and the drain are both disposed at a side of the second oxide layer away from the first oxide layer, the first oxide layer is a crystalline oxide layer, and the second oxide layer is a lanthanide oxide layer; and
wherein the gate is disposed at a side of the first oxide layer or the second oxide layer, and when the gate is disposed at a side of the first oxide layer away from the second oxide layer, an atomic proportion of an indium element in the first oxide layer is greater than an atomic proportion of an indium element in the second oxide layer; when the gate is disposed at the side of the second oxide layer away from the first oxide layer, the atomic proportion of the indium element in the first oxide layer is less than the atomic proportion of the indium element in the second oxide layer.

2. The thin film transistor according to claim 1, wherein the atomic proportion of the indium element in the first oxide layer gradually decreases in a direction away from the gate, and the atomic proportion of the indium element in the second oxide layer gradually decreases in the direction away from the gate.

3. The thin film transistor according to claim 2, wherein an atomic proportion of an oxygen element in the first oxide layer gradually increases in the direction away from the gate, and an atomic proportion of an oxygen element in the second oxide layer gradually increases in the direction away from the gate.

4. The thin film transistor according to claim 3, wherein a number of atoms of the indium element in the first oxide layer accounts for 50% to 100% of a number of atoms of a metal element in the first oxide layer, and a proportion of a number of atoms of the oxygen element in the first oxide layer ranges from more than 50%; a number of atoms of the indium element in the second oxide layer accounts for 50% to 100% of a number of atoms of a metal element in the second oxide layer, and a proportion of a number of atoms of the oxygen element in the second oxide layer ranges from more than 50%.

5. The thin film transistor according to claim 1, wherein a proportion of a number of atoms of lanthanide in the lanthanide oxide layer ranges from 0.05% to 3%.

6. The thin film transistor according to claim 1, further comprising a first auxiliary layer provided corresponding to the active layer, wherein the first auxiliary layer is disposed at the side of the first oxide layer away from the second oxide layer.

7. The thin film transistor according to claim 1, further comprising a second auxiliary layer provided corresponding to the active layer, wherein the second auxiliary layer is disposed at the side of the second oxide layer away from the first oxide layer.

8. The thin film transistor according to claim 7, wherein the second auxiliary layer comprises an insulating portion and conductor portions located at both sides of the insulating portion, and the conductor portions are provided corresponding to the source and the drain respectively.

9. An array substrate comprising a thin film transistor, wherein the thin film transistor comprises a gate, a source, a drain, and an active layer,
wherein the active layer comprises a first oxide layer and a second oxide layer that are stacked, the source and the drain are both disposed at a side of the second oxide layer away from the first oxide layer, the first oxide layer is a crystalline oxide layer, and the second oxide layer is a lanthanide oxide layer; and
wherein the gate is disposed at a side of the first oxide layer or the second oxide layer, and when the gate is disposed at a side of the first oxide layer away from the second oxide layer, an atomic proportion of an indium element in the first oxide layer is greater than an atomic proportion of an indium element in the second oxide layer; when the gate is disposed at the side of the second oxide layer away from the first oxide layer, the atomic proportion of the indium element in the first oxide layer is less than the atomic proportion of the indium element in the second oxide layer.

10. The array substrate according to claim 9, wherein the atomic proportion of the indium element in the first oxide layer gradually decreases in a direction away from the gate, and the atomic proportion of the indium element in the second oxide layer gradually decreases in the direction away from the gate.

11. The array substrate according to claim 10, wherein an atomic proportion of an oxygen element in the first oxide layer gradually increases in the direction away from the gate, and an atomic proportion of an oxygen element in the second oxide layer gradually increases in the direction away from the gate.

12. The array substrate according to claim 11, wherein a number of atoms of the indium element in the first oxide layer accounts for 50% to 100% of a number of atoms of a metal element in the first oxide layer, and a proportion of a number of atoms of the oxygen element in the first oxide layer ranges from more than 50%; a number of atoms of the indium element in the second oxide layer accounts for 50% to 100% of a number of atoms of a metal element in the second oxide layer, and a proportion of a number of atoms of the oxygen element in the second oxide layer ranges from more than 50%.

13. The array substrate according to claim 9, wherein a proportion of a number of atoms of lanthanide in the lanthanide oxide layer ranges from 0.05% to 3%.

14. The array substrate according to claim 9, wherein the thin film transistor further comprising a first auxiliary layer provided corresponding to the active layer, wherein the first auxiliary layer is disposed at the side of the first oxide layer away from the second oxide layer.

15. The array substrate according to claim 9, wherein the thin film transistor further comprising a second auxiliary layer provided corresponding to the active layer, wherein the second auxiliary layer is disposed at the side of the second oxide layer away from the first oxide layer.

16. The array substrate according to claim 15, wherein the second auxiliary layer comprises an insulating portion and conductor portions located at both sides of the insulating portion, and the conductor portions are provided corresponding to the source and the drain respectively.

17. A display panel comprising a first substrate and a second substrate that are arranged opposite to each other, wherein one of the first substrate and the second substrate comprises the array substrate of claim 9.
